(19) United States
(12) Patent Application Publication
(10) Pub. No.: US 2022/0068642 A1
(43) Pub. Date: Mar. 3, 2022

(54) SUBSTRATE PROCESSING METHOD AND SUBSTRATE PROCESSING DEVICE

(71) Applicant: Tokyo Electron Limited, Tokyo (JP)

(72) Inventors: Koji KAGAWA, Kumamoto (JP); Kenji SEKIGUCHI, Yamanashi (JP); Syuhei YONEZAWA, Yamanashi (JP); Daisuke SUZUKI, Yamanashi (JP); Yoshihiro TAKEZAWA, Yamanashi (JP); Yoshihisa MATSUBARA, Tokyo (JP)

(73) Assignee: Tokyo Electron Limited, Tokyo (JP)

(21) Appl. No.: 17/411,089

(22) Filed: Aug. 25, 2021

(30) Foreign Application Priority Data
Aug. 27, 2020 (JP) 2020-143215

(51) Int. Cl. H01L 21/02; H01L 21/67; H01L 21/324

(52) U.S. Cl. CPC H01L 21/02672; H01L 21/3247; H01L 21/67103

(57) ABSTRACT

A substrate processing method for crystallizing and expanding a silicon film by a thermal treatment, the method including: a holding process including holding, before executing the thermal treatment, a substrate on which the silicon film is formed; and an adhesion process including supplying, to the substrate that is held in the holding process, a solution containing metal to cause the metal to adhere to a surface of the silicon film with an adhesion amount within a range equal to or more than 1.0E10 [atoms/cm2] and equal to or less than 1.0E20 [atoms/cm2].

### CROSS-REFERENCE TO RELATED APPLICATION

The present application claims priority to and incorporates by reference the entire contents of Japanese Patent Application No. 2020-143215 filed in Japan on Aug. 27, 2020.

### FIELD

Exemplary embodiment disclosed herein relates to a substrate processing method and a substrate processing device.

### BACKGROUND

Patent literature 1 (Japanese Laid-open Patent Publication No. 2008-243975) discloses a technology for crystallizing a silicon film by executing, after forming a metal film as a catalyst on a surface of the silicon film, thereon a thermal treatment.

### SUMMARY

A substrate processing method according to one aspect of the present disclosure for crystallizing and expanding a silicon film by a thermal treatment includes: a holding process including holding, before executing the thermal treatment, a substrate on which the silicon film is formed; and an adhesion process including supplying, to the substrate that is held in the holding process, a solution containing metal to cause the metal to adhere to a surface of the silicon film with an adhesion amount within a range equal to or more than 1.0E10 [atoms/cm2] and equal to or less than 1.0E20 [atoms/cm2].

### BRIEF DESCRIPTION OF DRAWINGS

FIG. 1 is a diagram illustrating a schematic configuration of a substrate processing system according to an embodiment;

FIG. 2 is a diagram illustrating a schematic configuration of a first processing unit according to the embodiment;

FIG. 3 is a diagram illustrating a schematic configuration of a second processing unit according to the embodiment;

FIG. 4 is a flowchart illustrating a procedure for substrate processing executed by the first processing unit according to the embodiment;

FIG. 5 is a diagram illustrating one example of measurement result obtained by measuring a crystal size of a silicon film while changing an adhesion amount of metal in the substrate processing executed by the first processing unit; and

FIG. 6 is a flowchart illustrating a procedure for substrate processing executed by the second processing unit according to the embodiment.

### DESCRIPTION OF EMBODIMENTS

Hereinafter, exemplary embodiments will be described in detail with reference to the accompanying drawings. In addition, the illustrative embodiments disclosed below are not intended to limit the disclosed technology.

The embodiment provide a technology capable of appropriately crystallizing and expanding a silicon film.

Incidentally, in a case where metal as a catalyst is caused to adhere to a surface of a silicon film and then a thermal treatment is executed thereon, there presents possibility that metal excessively diffuses into the silicon film, and as a result, crystallization and expansion of the silicon film are prevented due to the excessively diffused metal. Thus, it has been desired to appropriately crystallize and expand a silicon film.

### Embodiment

Configuration of Substrate Processing System

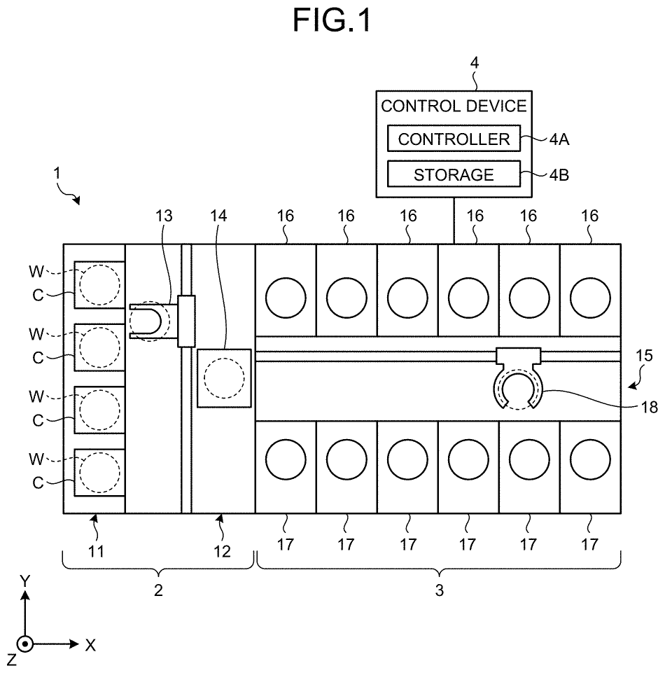

FIG. 1 is a diagram illustrating a schematic configuration of a substrate processing system 1 according to the embodiment. Hereinafter, in order to clarify positional relationship, there are defined an X-axis, a Y-axis, and a Z-axis that are perpendicular to one another, and a positive direction of the Z-axis is defined as a vertically upward direction.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. In the carrier placing section 11, a plurality of carriers C is placed to horizontally accommodate a plurality of semiconductor wafers (hereinafter, may be referred to as wafers W) in the present embodiment. Moreover, a silicon film is formed on a surface of the wafer W.

The transfer section 12 is provided adjacent to the carrier placing section 11, and includes therein a substrate transfer device 13 and a delivery unit 14. The substrate transfer device 13 includes a wafer holding mechanism configured to hold the wafer W. The substrate transfer device 13 is movable horizontally and vertically and is pivotable around a vertical axis, and transfers the wafer W between the carrier C and the delivery unit 14 by using the wafer holding mechanism.

The processing station 3 is provided adjacent to the transfer section 12. The processing station 3 includes a transfer section 15, a plurality of first processing units 16, and a plurality of second processing units 17. The plurality of first processing units 16 and the plurality of second processing units 17 are provided side by side at both sides of the transfer section 15.

The transfer section 15 includes therein a substrate transfer device 18. The substrate transfer device 18 includes a wafer holding mechanism configured to hold the wafer W. The substrate transfer device 18 is movable horizontally and vertically and is pivotable around a vertical axis, and transfers the wafer W between the delivery unit 14 and the processing unit 16 or the second processing unit 17 by using the wafer holding mechanism.

Each of the first processing units 16 performs a predetermined process on the wafer W transferred by the substrate transfer device 18. In the present embodiment, the first processing unit 16 causes metal as a catalyst to adhere to a surface of a silicon film before execution of a thermal treatment for crystallizing and expanding the silicon film on the wafer W.

Each of the second processing units 17 performs a predetermined process on the wafer W transferred by the substrate transfer device 18. In the present embodiment, the second processing unit 17 removes metal (for example, metal silicide) remaining on a surface of a silicon film after execution of the thermal treatment for crystallizing and expanding the silicon film on the wafer W.

The substrate processing system 1 further includes a control device 4. The control device 4 is a computer, for example, and includes a controller 4A and a storage 4B. The storage 4B stores therein a program for controlling various types of processes that are performed in the substrate processing system 1. The controller 4A reads out and executes a program stored in the storage 4B to control operations of the substrate processing system 1.

The program may be recorded in a computer-readable recording medium and thus may be installed into the storage 4B of the control device 4 from the recording medium. A computer-readable recording medium includes, for example, a hard disk (HD), a flexible disk (FD), a compact disc (CD), a magneto-optical disk (MO), and a memory card among other things.

In the substrate processing system 1 configured as described above, the substrate transfer device 13 of the carry-in/out station 2 first takes out the wafer W from one of the carriers C placed in the carrier placing section 11, and places the taken wafer W on the delivery unit 14. The wafer W placed on the delivery unit 14 is taken out from the delivery unit 14 by the substrate transfer device 18 of the processing station 3, and is carried into one of the first processing units 16.

The wafer W carried into the first processing unit 16 is processed by the first processing unit 16, and then is carried out from the first processing unit 16 and placed on the delivery unit 14 by using the substrate transfer device 18. The processed wafer W placed on the delivery unit 14 is returned to the carrier C in the carrier placing section 11 by the substrate transfer device 13.

After the processed wafer W is returned to the carrier C, the carriers C is transferred to an annealing device arranged outside of the substrate processing system 1 by a predetermined transfer device. In the annealing device, a thermal treatment is executed on the wafer W. The carrier C accommodating the wafer W on which the thermal treatment is executed is returned to the substrate processing system 1 by a predetermined transfer device.

Next, in the substrate processing system 1, the substrate transfer device 13 takes out the wafer W from the carrier C placed in the carrier placing section 11, and places the taken wafer W on the delivery unit 14. The wafer W placed on the delivery unit 14 is taken out from the delivery unit 14 by the substrate transfer device 18 of the processing station 3, and is carried into the second processing unit 17.

The wafer W carried into the second processing unit 17 is processed by the second processing unit 17, and then is carried out from the second processing unit 17 by the substrate transfer device 18 so as to be placed on the delivery unit 14. Next, the processed wafer W placed on the delivery unit 14 is returned to the carrier C in the carrier placing section 11 by the substrate transfer device 13.

Configuration of First Processing Unit

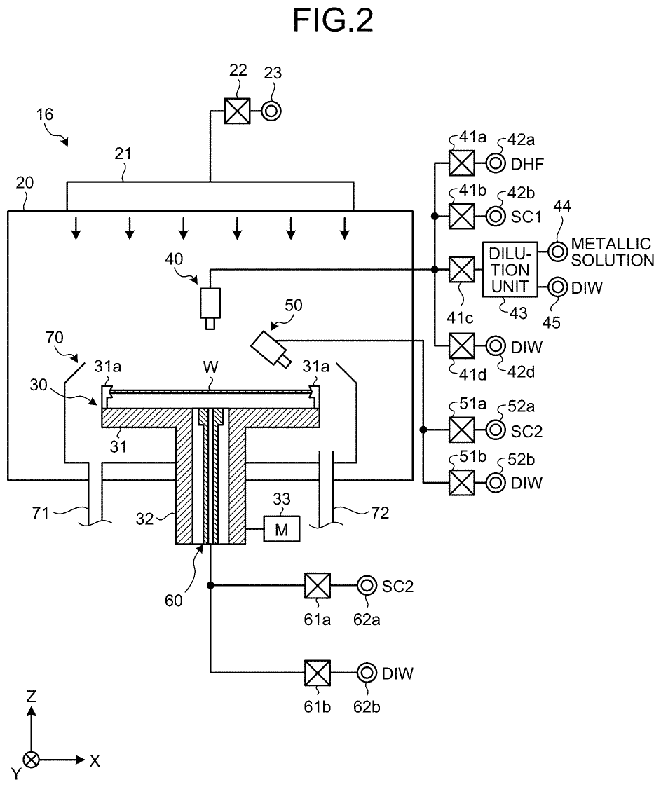

Next, a schematic configuration of the first processing unit 16 will be explained with reference to FIG. 2. FIG. 2 is a diagram illustrating a schematic configuration of the first processing unit 16 according to the embodiment.

As illustrated in FIG. 2, the first processing unit 16 includes a chamber 20, a substrate holding mechanism 30, a processing-liquid supplying unit 40, a cleaning-liquid supplying unit 50, a lower supply unit 60, and a recovery cup 70.

The chamber 20 accommodates the substrate holding mechanism 30, the processing-liquid supplying unit 40, the cleaning-liquid supplying unit 50, the lower supply unit 60, and the recovery cup 70. A Fan Filter Unit (FFU) 21 is arranged in a ceiling portion of the chamber 20. The FFU 21 forms down-flow in the chamber 20.

The FFU 21 is connected to a down-flow-gas supplying source 23 via a valve 22. The FFU 21 discharges, into the chamber 20, down-flow gas (for example, nitrogen or dried air) supplied from the down-flow-gas supplying source 23.

The substrate holding mechanism 30 includes a holding unit 31, a supporting unit 32, and a drive unit 33. The holding unit 31 horizontally holds the wafer W. A plurality of gripping units 31a configured to grip a periphery portion of the wafer W is arranged on an upper surface of the holding unit 31. The wafer W is horizontally held by the gripping units 31a in a state where the wafer W is slightly separated from the upper surface of the holding unit 31. The wafer W is held by the holding unit 31 in a state where a surface thereof on which a silicon film is formed directs upward. The supporting unit 32 is a member extending in the vertical direction so as to support the holding unit 31 from a lower portion thereof. The drive unit 33 rotates the supporting unit 32 around a vertical axis. The substrate holding mechanism 30 causes the drive unit 33 to rotate the supporting unit 32, and accordingly rotate the holding unit 31 supported by the supporting unit 32 so as to rotate the wafer W held by the holding unit 31.

The processing-liquid supplying unit 40 supplies various processing liquids to the wafer W held by the substrate holding mechanism 30. The processing-liquid supplying unit 40 is connected to a dilute hydrofluoric acid (DHF) supplying source 42a via a valve 41a. The processing-liquid supplying unit 40 is connected to an SC1 supplying source 42b via a valve 41b. DHF supplied from the DHF supplying source 42a and SC1 (mixed solution of ammonia, hydrogen peroxide, and water) supplied from the SC1 supplying source 42b are hydrophilization processing liquids for hydrophilizing a surface of a silicon film formed on the wafer W.

The processing-liquid supplying unit 40 is connected to a metallic-solution supplying source 44 and a DeIonized Water (DIW) supplying source 45 via a valve 41c and a dilution unit 43. Solution (hereinafter, may be referred to “metallic solution”) supplied from the metallic-solution supplying source 44 contains metal, and is a processing liquid for causing metal to adhere to a surface of a silicon film formed on the wafer W. As the metal contained in the metallic solution, at least one of, for example, Ni, Pd, Ag, Au, Sn, Sb, Cu, Cd, Al, Co, Pt, Mo, Ti, W, and Cr is used. As a solvent of the metallic solution, for example, dilute nitric acid, deionized water, or the like is used. DIW supplied from the DIW supplying source 45 is diluting liquid for diluting metallic solution. Instead of DIW, isopropyl alcohol (IPA) may be used as the diluting liquid. The metallic solution supplied from the metallic-solution supplying source 44 is diluted by using DIW in a dilution unit 43 to be supplied to the wafer W from the processing-liquid supplying unit 40.

In terms of reducing a contact angle of metallic solution with respect to the wafer W so as to facilitate adhesion of metal to a surface of a silicon film, mixed solution obtained by mixing an organic solvent such as IPA with metallic solution may be supplied to the wafer W from the processing-liquid supplying unit 40. In this case, instead of the metallic-solution supplying source 44, a mixed-solution supplying source may be used which supplies mixed solution obtained by mixing an organic solvent such as IPA with metallic solution.

The processing-liquid supplying unit 40 is connected to a DIW supplying source 42d via a valve 41d. DIW supplied from the DIW supplying source 42d is diluting liquid for further diluting metallic solution that is diluted by the dilution unit 53. As the diluting liquid, instead of DIW, IPA may be used. Note that DIW supplied from the DIW supplying source 42d is also used as cleaning liquid for cleaning metal excessively adhering to a surface of a silicon film formed on the wafer W. DIW supplied from the DIW supplying source 42d is also used as processing liquid for rinsing in order to remove hydrophilization processing liquid.

The cleaning-liquid supplying unit 50 supplies cleaning liquid for cleaning a bevel portion of the wafer W held by the substrate holding mechanism 30. The bevel portion is a slope that is formed in a periphery portion of the wafer W. The cleaning-liquid supplying unit 50 is connected to an SC2 supplying source 52a via a valve 51a. SC2 (mixed solution of hydrochloric acid and hydrogen peroxide) supplied from the SC2 supplying source 52a is cleaning liquid for cleaning the bevel portion of the wafer W. As the cleaning liquid, instead of SC2, hydrofluoric acid, dilute hydrochloric acid, SPM (mixed solution of sulfuric acid and hydrogen peroxide), or aqua regia (mixed solution of hydrochloric acid and nitric acid in ratio of three to one) may be used.

The cleaning-liquid supplying unit 50 is connected to a DIW supplying source 52b via a valve 51b. DIW supplied from the DIW supplying source 52b is processing liquid for rinsing in order to remove cleaning liquid remaining on the bevel portion of the wafer W.

The lower supply unit 60 supplies cleaning liquid for cleaning a back surface of the wafer W held by the substrate holding mechanism 30. The back surface is opposite to a surface of the wafer W on which a silicon film is formed. The lower supply unit 60 is inserted into a hollow portion of the holding unit 31 and the supporting unit 32. A flow path extending in the vertical direction is formed in the lower supply unit 60. The flow path is connected to a SC2 supplying source 62a via a valve 61a. SC2 supplied from the SC2 supplying source 62a is cleaning liquid for cleaning the back surface of the wafer W. As the cleaning liquid, instead of SC2, hydrofluoric acid, dilute hydrochloric acid, SPM, or aqua regia may be used.

The lower supply unit 60 is connected to a DIW supplying source 62b via a valve 61b. DIW supplied from the DIW supplying source 62b is processing liquid for rinsing in order to remove cleaning liquid remaining on the back surface of the wafer W.

The recovery cup 70 is formed so as to surround the holding unit 31, and collects processing liquid splashed from the wafer W due to rotation of the holding unit 31. A drain port 71 is formed in a bottom portion of the recovery cup 70, and processing liquid collected by the recovery cup 70 is discharged to the outside of the first processing unit 16 from the above-mentioned drain port 71. In the bottom portion of the recovery cup 70, an exhaust port 72 is formed which exhausts gas supplied from the FFU 21 to the outside of the first processing unit 16.

Configuration of Second Processing Unit

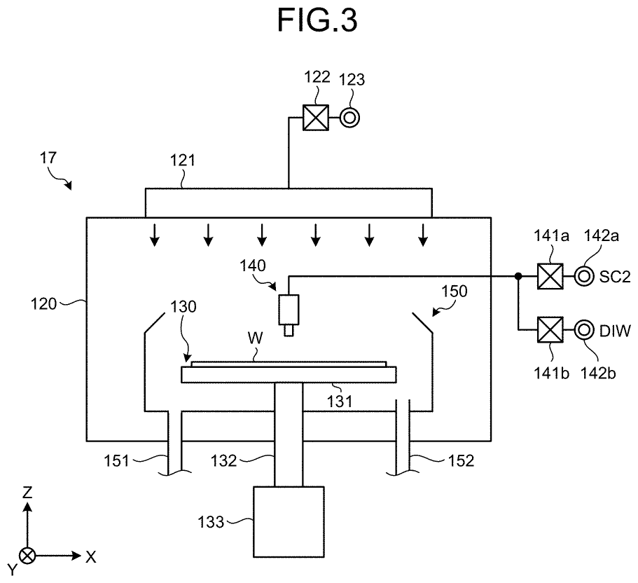

Next, a schematic configuration of the second processing units 17 will be explained with reference to FIG. 3. FIG. 3 is a diagram illustrating a schematic configuration of the second processing unit 17 according to the embodiment.

As illustrated in FIG. 3, each of the second processing units 17 includes a chamber 120, a substrate holding mechanism 130, a supply unit 140, and a recovery cup 150.

The chamber 120 accommodates the substrate holding mechanism 130, the supply unit 140, and the recovery cup 150. The wafer W on which a thermal treatment has been executed by an annealing device is transferred into the chamber 120. Metal (namely, metal silicide) silicidized in the thermal treatment is remaining on a surface of a silicon film of the wafer W on which the thermal treatment has been executed by the annealing device. An FFU 121 is arranged in a ceiling portion of the chamber 120. The FFU 121 forms down-flow in the chamber 120.

The FFU 121 is connected to a down-flow-gas supplying source 123 via a valve 122. The FFU 121 discharges, into the chamber 120, down-flow gas (for example, nitrogen or dried air) supplied from the down-flow-gas supplying source 123.

The substrate holding mechanism 130 includes a holding unit 131, a supporting unit 132, and a drive unit 133. The holding unit 131 horizontally holds the wafer W. The wafer W is held by the holding unit 131 in a state where a surface thereof on which a silicon film is formed directs upward. The supporting unit 132 is a member extending in the vertical direction so as to support the holding unit 131 from a lower portion thereof. The drive unit 133 rotates the supporting unit 132 around a vertical axis. The substrate holding mechanism 130 causes the drive unit 133 to rotate the supporting unit 132, and accordingly rotate the holding unit 131 supported by the supporting unit 132 so as to rotate the wafer W held by the holding unit 131.

The supply unit 140 supplies processing liquid to the wafer W held by the substrate holding mechanism 130. The supply unit 140 is connected to an SC2 supplying source 142a via a valve 141a. SC2 supplied from the SC2 supplying source 142a is cleaning liquid for removing metal (for example, metal silicide) remaining on a surface of a silicon film. As the cleaning liquid for removing metal remaining on the surface of the silicon film, instead of SC2, SPM or aqua regia may be used.

The supply unit 140 is connected to a DIW supplying source 142b via a valve 141b. DIW supplied from the DIW supplying source 142b is processing liquid for rinsing in order to remove cleaning liquid remaining on a surface of a silicon film.

The recovery cup 150 is formed so as to surround the holding unit 131, and collects processing liquid splashed from the wafer W due to rotation of the holding unit 131. A drain port 151 is formed in a bottom portion of the recovery cup 150, and processing liquid collected by the recovery cup 150 is discharged to the outside of the second processing unit 17 from the above-mentioned drain port 151. In a bottom portion of the recovery cup 150, an exhaust port 152 is formed which exhausts gas supplied from the FFU 121 to the outside of the second processing unit 17.

Substrate Processing to be Executed by First Processing Unit

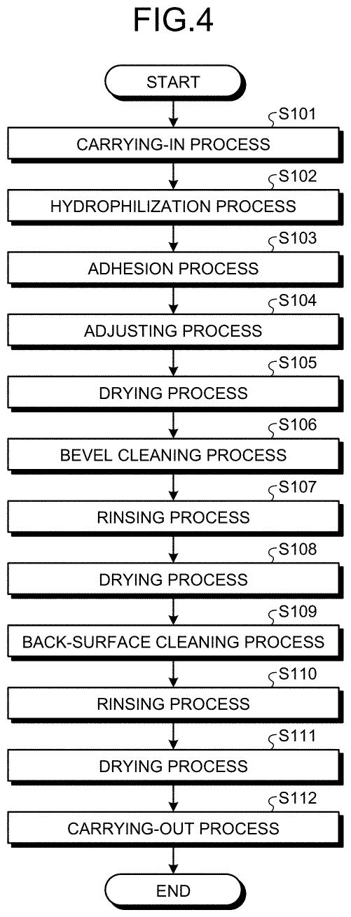

Next, substrate processing to be executed by the first processing unit 16 will be explained with reference to FIG. 4. FIG. 4 is a flowchart illustrating a procedure for substrate processing executed by the first processing unit 16 according to the embodiment. The processes illustrated in FIG. 4 are executed in accordance with control of the controller 4A.

As illustrated in FIG. 4, the substrate transfer device 18 first carries the wafer W into the chamber 20 of the first processing unit 16 (Step S101). The wafer W is held by the holding unit 31 in a state where a surface thereof on which a silicon film is formed directs upward. Next, the drive unit 33 causes the holding unit 31 to rotate. Thus, the wafer W rotates together with the holding unit 31.

Subsequently, a hydrophilization process is executed in the first processing unit 16 (Step S102). In the hydrophilization process, the processing-liquid supplying unit 40 is positioned above the center of the wafer W. Next, the valve 41a is released for a predetermined time interval, and thus DHF of hydrophilization processing liquid is supplied to a surface of the wafer W. DHF supplied to the wafer W spreads over a whole surface of a silicon film formed on the wafer W caused by a centrifugal force according to rotation of the wafer W. Thus, the surface of the silicon film formed on the wafer W is hydrophilized. Next, the valve 41d is released for a predetermined time interval, and thus DIW of processing liquid for rinsing is supplied to the surface of the wafer W. DIW supplied to the wafer W spreads over a whole surface of the silicon film formed on the wafer W caused by a centrifugal force according to rotation of the wafer W. Thus, DHF remaining on the surface of the wafer W is washed away by DIW. Next, the valve 41b is released for a predetermined time interval, and thus SC1 of hydrophilization processing liquid is supplied to the surface of the wafer W. SC1 supplied to the wafer W spreads over a whole surface of the silicon film formed on the wafer W caused by a centrifugal force according to rotation of the wafer W. Thus, a surface of the silicon film formed on the wafer W is further hydrophilized. Next, the valve 41d is released for a predetermined time interval, and thus DIW of processing liquid for rinsing is supplied to the surface of the wafer W. DIW supplied to the wafer W spreads over a whole surface of the silicon film formed on the wafer W caused by a centrifugal force according to rotation of the wafer W. Thus, SC1 remaining on the surface of the wafer W is washed away by DIW.

Next, an adhesion process is executed in the first processing unit 16 (Step S103). In the adhesion process, the valve 41c and the valve 41d are released for a predetermined time interval, and thus metallic solution is supplied to a surface of the wafer W. In this case, the metallic solution is diluted by DIW that is supplied from the DIW supplying source 45 in the dilution unit 43, and is further diluted, on a downstream side of the dilution unit 43, by DIW supplied from the DIW supplying source 42d, so as to be supplied to the surface of the wafer W. In other words, in the adhesion process, metallic solution is diluted step by step by a plurality of diluting liquids (DIW) before the metallic solution is supplied to the wafer W so as to adjust a concentration of metal contained in the metallic solution. A concentration of metal contained in the metallic solution is within a range equal to or more than 10 [ppm] and equal to or less than 10000 [ppm], for example. The metallic solution supplied to the wafer W spreads over a whole surface of a silicon film formed on the wafer W caused by a centrifugal force according to rotation of the wafer W. Thus, metal adheres to a surface of a silicon film formed on the wafer W with an adhesion amount within a range equal to or more than 1.0E10 [atoms/cm2] and equal to or less than 1.0E20 [atoms/cm2].

Note that in the above-mentioned adhesion process, when a concentration of metal contained in metallic solution is desired one by the first dilution of the dilution unit 43, the second dilution on the downstream side of the dilution unit 43 may be omitted.

Note that in the above-mentioned adhesion process, the first processing unit 16 may form a puddle of metallic solution on the wafer W, and then further may increase a rotational speed of the wafer W for a predetermined time interval so as to fly away the metallic solution on the wafer W. When metallic solution is supplied while reducing a rotational speed of the wafer W for a predetermined time interval (or stopping rotation of wafer W for predetermined time interval), the puddle of metallic solution is able to be obtained. When metallic solution is flown away after a puddle of metallic solution is formed on the wafer W, a supply amount of the metallic solution to the wafer W is able to be reduced.

Note that in the above-mentioned adhesion process, the first processing unit 16 may supply atomized metallic solution to a surface of the wafer W by using a two-fluid nozzle or the like. Note that in the above-mentioned adhesion process, the first processing units 16 may execute a scanning process for moving the processing-liquid supplying unit 40 between a center portion and a peripheral portion of the wafer W so as to supply metallic solution to a surface of the wafer W. Thus, it is possible to reduce a processing time interval of the adhesion process.

The first processing unit 16 may supply, to the wafer W, mixed solution obtained by mixing metallic solution with organic solvent such as IPA. Thus, a contact angle of metallic solution with respect to the wafer W is able to be reduced so that it is possible to easily spread the metallic solution over a surface of a silicon film formed on the wafer W. Thus, it is possible to facilitate adhesion of metal to a surface of the silicon film. Moreover, when mixed solution obtained by mixing metallic solution with organic solvent is used, the first processing unit 16 may supply mixed solution to the wafer W so as to obtain a thickness of equal to or more than 100 nm, for example. Thus, it is possible to facilitate adhesion of metal to a surface of the silicon film.

Preferably, in the above-mentioned adhesion process, a rotational speed of the wafer W is set to equal to or less than 1000 [rpm], and a processing time interval is set to equal to or less than 60 seconds.

Next, in the first processing unit 16, an adjusting process is executed (Step S104). Next, in the adjusting process, the valve 41d is released for a predetermined time interval, and thus DIW of cleaning liquid is supplied to a surface of the wafer W. DIW supplied to the wafer W spreads over a whole surface of the silicon film formed on the wafer W caused by a centrifugal force according to rotation of the wafer W. Thus, a part of metal adhering to a surface of a silicon film formed on the wafer W is washed away by DIW. Thus, it is possible to adjust an adhesion amount of metal on the surface of the silicon film.

In a case where an adhesion amount of metal on the surface of the silicon film is a desired one at a timing when the above-mentioned adhesion process (Step S103) ends, the above-mentioned adjusting process (Step S104) may be omitted.

Next, in the first processing unit 16, a drying process is executed (Step S105). In the drying process, a rotational speed of the wafer W is increased for a predetermined time interval, and DIW remaining on the wafer W is flown away so as to perform spin-dry on the wafer W.

A drying method employed in the above-mentioned drying process is not limited to the spin drying. For example, IPA drying may be performed in which DIW is replaced with IPA and then the IPA is flown away so as to spin-dry the wafer W. In terms of preventing pattern collapse on the wafer W, before the IPA drying, hydrophobization liquid may be supplied to the wafer W so as to hydrophobize a surface of the wafer W. In the above-mentioned drying process, supercritical drying may be performed in which DIW is replaced with IPA and then the IPA is in contact with fluid in a supercritical state so as to dry the wafer W.

Next, in the first processing unit 16, a bevel cleaning process is executed (Step S106). In the bevel cleaning process, the cleaning-liquid supplying unit 50 is positioned above a periphery portion of the wafer W. Thereafter, the valve 51a is released for a predetermined time interval, and SC2 of cleaning liquid is supplied to the periphery portion of the wafer W. Thus, the bevel portion of the wafer W is cleaned and metal is removed from the bevel portion of the wafer W.

Next, in the first processing unit 16, a rinsing process is executed (Step S107). In the rinsing process, the valve 51b is released for a predetermined time interval, and DIW of processing liquid for rinsing is supplied to the periphery portion of the wafer W. Thus, SC2 remaining on the bevel portion of the wafer W is washed away by DIW.

Next, in the first processing unit 16, a drying process is executed (Step S108). In the drying process, a rotational speed of the wafer W is increased for a predetermined time interval so as to dry the wafer W.

Next, in the first processing unit 16, a back-surface cleaning process is executed (Step S109). In the back-surface cleaning process, the valve 61a is released for a predetermined time interval, and thus SC2 of cleaning liquid is supplied to the back surface of the wafer W. SC2 supplied to the back surface of the wafer W spreads over a whole back surface of the wafer W caused by a centrifugal force according to rotation of the wafer W. Thus, the back surface of the wafer W is cleaned and metal is removed from the back surface of the wafer W.

Next, in the first processing unit 16, a rinsing process is executed (Step S110). In the rinsing process, the valve 61b is released for a predetermined time interval, and thus DIW of processing liquid for rinsing is supplied to the back surface of the wafer W. Thus, SC2 remaining on the back surface of the wafer W is washed away by DIW.

Next, in the first processing unit 16, a drying process is executed (Step S111). In the drying process, a rotational speed of the wafer W is increased for a predetermined time interval so as to dry the wafer W.

Subsequently, in the first processing unit 16, a carrying-out process is executed (Step S112). In the carrying-out process, rotation of the wafer W is stopped, and then the wafer W is carried out from the first processing unit 16. The wafer W carried out from the first processing unit 16 is returned to the carrier C of the carrier placing section 11, and then is transferred to an annealing device that is arranged in the outside of the substrate processing system 1. In the annealing device, a thermal treatment is executed on the wafer W. A processing time interval of the thermal treatment is 2 hours to 24 hours, for example. When the thermal treatment is executed on the wafer W, metal adhering to a surface of a silicon film formed on the wafer W diffuses into the silicon film so as to be silicidized. Thus, the silicon film is crystallized and expands from the silicidized metal (namely, metal silicide). The wafer W on which the thermal treatment is executed is housed in the carrier C, and then is returned to the substrate processing system 1.

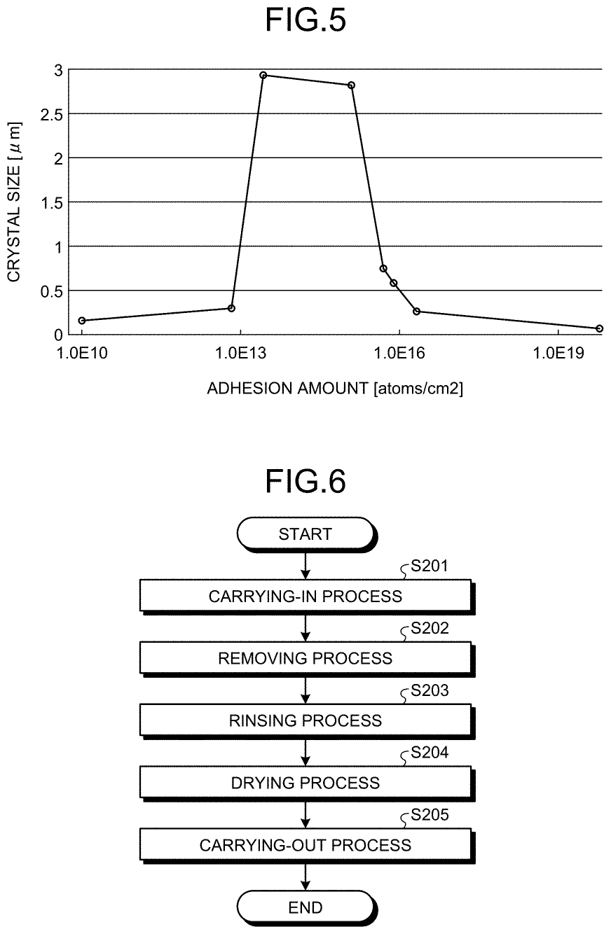

Herein, relationship between an adhesion amount of metal and crystallization of a silicon film in the substrate processing to be executed by the first processing unit 16 was evaluated. FIG. 5 is a diagram illustrating one example of measurement result obtained by measuring a crystal size of a silicon film while changing an adhesion amount of metal in the substrate processing executed by the first processing unit 16. Ni was employed as the metal.

As obvious from FIG. 5, when an adhesion amount of metal to a surface of a silicon film was within a range equal to or more than 1.0E10 [atoms/cm2] and equal to or less than 1.0E20 [atoms/cm2], a silicon film having a crystal size of greater than 0 [μm] was obtained. Particularly, when an adhesion amount of metal to a surface of a silicon film was within a range equal to or more than 1.0E13 [atoms/cm2] and equal to or less than 1.0E16 [atoms/cm2], a crystal size was equal to or more than approximately 0.5 [μm]. Thus, it was confirmed that a preferable adhesion amount of metal in terms of appropriately crystallizing and expanding a silicon film was within the following range. In other words, an adhesion amount of metal was preferably within a range equal to or more than 1.0E10 [atoms/cm2] and equal to or less than 1.0E20 [atoms/cm2], and was more preferably within a range equal to or more than 1.0E13 [atoms/cm2] and equal to or less than 1.0E16 [atoms/cm2].

Substrate Processing to be Executed by Second Processing Unit

Next, substrate processing to be executed by the second processing unit 17 will be explained with reference to FIG. 6. FIG. 6 is a flowchart illustrating a procedure for the substrate processing executed by the second processing unit 17 according to the embodiment. The processes illustrated in FIG. 6 are executed in accordance with control of the controller 4A.

As illustrated in FIG. 6, the substrate transfer device 18 first carries the wafer W into the chamber 120 of the second processing unit 17 (Step S201). The wafer W on which a thermal treatment has been executed by an annealing device is carried into the chamber 120. Metal (namely, metal silicide) silicidized in the thermal treatment is remaining on a surface of a silicon film of the wafer W on which the thermal treatment has been executed by the annealing device. The wafer W is held by the holding unit 131 in a state where a surface thereof on which a silicon film is formed directs upward. Next, the drive unit 133 causes the holding unit 131 to rotate. Thus, the wafer W rotates together with the holding unit 131.

Subsequently, in the second processing unit 17, a removing process is executed (Step S202). In the removing process, the supply unit 140 is positioned above the center of the wafer W. Next, the valve 141a is released for a predetermined time interval, and thus SC2 of cleaning liquid is supplied to a surface of the wafer W. SC2 supplied to the wafer W spreads over a whole surface of a silicon film formed on the wafer W caused by a centrifugal force according to rotation of the wafer W. Thus, metal (for example, metal silicide) remaining on the surface of the silicon film is removed.

Next, in the second processing unit 17, a rinsing process is executed (Step S203). In the rinsing process, the valve 141b is released for a predetermined time interval, and thus DIW of processing liquid for rinsing is supplied to the surface of the wafer W. DIW supplied to the wafer W spreads over a whole surface of the silicon film formed on the wafer W caused by a centrifugal force according to rotation of the wafer W. Thus, SC2 remaining on the surface of the wafer W is washed away by DIW.

Next, in the second processing unit 17, a drying process is executed (Step S204). In the drying process, a rotational speed of the wafer W is increased for a predetermined time interval so as to dry the wafer W.

Next, in the second processing unit 17, a carrying-out process is executed (Step S205). In the carrying-out process, rotation of the wafer W is stopped, and then the wafer W is carried out from the second processing unit 17.

Effects

A substrate processing method according to the embodiment for crystallizing and expanding a silicon film by a thermal treatment includes a holding process and an adhesion process. The holding process includes holding, before executing the thermal treatment, a substrate (one example of wafer W) on which the silicon film is formed. The adhesion process includes supplying, to the substrate that is held in the holding process, a solution containing metal to cause the metal to adhere to a surface of the silicon film with an adhesion amount within a range equal to or more than 1.0E10 [atoms/cm2] and equal to or less than 1.0E20 [atoms/cm2]. Thus, according to the embodiment, it is possible to appropriately crystallize and expand a silicon film.

The adhesion process may include diluting, before the solution containing the metal is supplied to the substrate, the solution by using a diluting liquid to adjust a concentration of the metal contained in the solution. Thus, according to the embodiment, it is possible to adjust an adhesion amount of metal to a surface of a silicon film, and further to adjust a crystal size of the silicon film to a desired one.

The adhesion process may include diluting step by step the solution by using a plurality of diluting liquids to adjust a concentration of the metal contained in the solution. Thus, according to the embodiment, it is possible to more precisely adjust an adhesion amount of metal to a surface of a silicon film, and further to improve accuracy in adjustment of a crystal size of the silicon film.

A concentration of the metal contained in the solution may be within a range equal to or more than 10 [ppm] and equal to or less than 10000 [ppm]. Thus, according to the embodiment, it is possible to optimize an adhesion amount of metal to a surface of a silicon film, and further to adjust a crystal size of the silicon film to a desired one.

The substrate processing method according to the embodiment may include a hydrophilization process. The hydrophilization process includes hydrophilizing a surface of the silicon film. The adhesion process may include supplying the solution containing the metal to the substrate in a state where the surface of the silicon film is hydrophilized in the hydrophilization process. Thus, according to the embodiment, it is possible to improve contact of solution with a substrate, and further to facilitate adhesion of metal to a surface of a silicon film.

The adhesion process may include forming a puddle of the solution containing the metal on the substrate, and then flying away the solution containing the metal. Thus, according to the embodiment, it is possible to reduce a supply amount of metallic solution to a substrate.

The adhesion process may include supplying, to the substrate, a mixed solution in which the solution containing the metal and an organic solvent are mixed. The adhesion process may include supplying, to the substrate, the mixed solution in which the solution containing the metal and the organic solvent are mixed such that a thickness of the mixed solution is equal to or more than 100 nm. Thus, according to the embodiment, it is possible to reduce a contact angle of solution with respect to a substrate, and further to facilitate adhesion of metal to a surface of a silicon film.

The metal contained in the solution may include at least one of Ni, Pd, Ag, Au, Sn, Sb, Cu, Cd, Al, Co, Pt, Mo, Ti, W, and Cr. Thus, according to the embodiment, it is possible to crystallize and expand a silicon film from each of various metal silicides.

The substrate processing method according to the embodiment may further include an adjusting process. The adjusting process includes supplying, after the adhesion process, a cleaning liquid to the substrate to adjust an adhesion amount of the metal to the surface of the silicon film. Thus, according to the embodiment, it is possible to adjust an adhesion amount of metal to a surface of a silicon film, and further to adjust a crystal size of the silicon film to a desired one.

The substrate processing method according to the embodiment may further include a bevel cleaning process. The bevel cleaning process includes cleaning, after the adhesion process, a bevel portion of the substrate. Thus, according to the embodiment, it is possible to avoid contamination by metal in a transfer system when a substrate is transferred to a device (one example of annealing device) that executes a post-process that is a thermal treatment.

The substrate processing method according the embodiment may further include a back-surface cleaning process. The back-surface cleaning process includes cleaning, after the adhesion process, a back surface of the substrate. Thus, according to the embodiment, it is possible to avoid contamination by metal in a transfer system when a substrate is transferred to a device (one example of annealing device) that executes a post-process that is a thermal treatment.

The substrate processing method according to the embodiment may further include a removing process. The removing process includes removing, after executing the thermal treatment, the metal that is remaining on the surface of the silicon film. Thus, according to the embodiment, it is possible to appropriately remove silicidized metal from a surface of a silicon film.

Modification

The substrate processing system 1 according to the above-mentioned embodiment causes an annealing device that is arranged in the outside of the substrate processing system 1 to execute a thermal treatment; however, the present disclosed technology is not limited thereto. For example, an annealing device may be provided in the substrate processing system 1, and further may cause the annealing device to execute the thermal treatment.

The substrate processing system 1 according to a modification may execute a cup cleaning process that includes discharging, after executing the carrying-out process (Step S112), a cleaning liquid from a not-illustrated supply unit to an inner wall of the recovery cup 70, and cleaning metal and the like remaining on the inner wall of the recovery cup 70.

According to the embodiment, it is possible to appropriately crystallize and expand a silicon film.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing method for crystallizing and expanding a silicon film by a thermal treatment, the method comprising:
a holding process including:
holding, before executing the thermal treatment, a substrate on which the silicon film is formed; and
an adhesion process including:
supplying, to the substrate that is held in the holding process, a solution containing metal to cause the metal to adhere to a surface of the silicon film with an adhesion amount within a range equal to or more than 1.0E10 [atoms/cm2] and equal to or less than 1.0E20 [atoms/cm2].

2. The substrate processing method according to claim 1, wherein
the adhesion process includes diluting, before the solution containing the metal is supplied to the substrate, the solution by using a diluting liquid to adjust a concentration of the metal contained in the solution.

3. The substrate processing method according to claim 1, wherein
the adhesion process includes diluting step by step the solution by using a plurality of diluting liquids to adjust a concentration of the metal contained in the solution.

4. The substrate processing method according to claim 1, wherein
a concentration of the metal contained in the solution is within a range equal to or more than 10 [ppm] and equal to or less than 10000 [ppm].

5. The substrate processing method according to claim 1 further comprising:
a hydrophilization process including:
hydrophilizing a surface of the silicon film, wherein
the adhesion process includes supplying the solution containing the metal to the substrate in a state where the surface of the silicon film is hydrophilized in the hydrophilization process.

6. The substrate processing method according to claim 1, wherein
the adhesion process includes forming a puddle of the solution containing the metal on the substrate, and then flying away the solution containing the metal.

7. The substrate processing method according to claim 1, wherein
the adhesion process includes supplying, to the substrate, a mixed solution in which the solution containing the metal and an organic solvent are mixed.

8. The substrate processing method according to claim 7, wherein
the adhesion process includes supplying, to the substrate, the mixed solution in which the solution containing the metal and the organic solvent are mixed such that a thickness of the mixed solution is equal to or more than 100 nm.

9. The substrate processing method according to claim 1, wherein
the metal contained in the solution includes at least one of Ni, Pd, Ag, Au, Sn, Sb, Cu, Cd, Al, Co, Pt, Mo, Ti, W, and Cr.

10. The substrate processing method according to claim 1 further comprising:
an adjusting process including:
supplying, after the adhesion process, a cleaning liquid to the substrate to adjust an adhesion amount of the metal to the surface of the silicon film.

11. The substrate processing method according to claim 1 further comprising:
a bevel cleaning process including:
cleaning, after the adhesion process, a bevel portion of the substrate.

12. The substrate processing method according to claim 1 further comprising:
a back-surface cleaning process including:
cleaning, after the adhesion process, a back surface of the substrate.

13. The substrate processing method according to claim 1 further comprising:
a removing process including:
removing, after executing the thermal treatment, the metal that is remaining on the surface of the silicon film.

14. A substrate processing device used for a substrate processing method for crystallizing and expanding a silicon film by a thermal treatment, the device comprising:
a holding unit that holds a substrate;
a supply unit that supplies, to the substrate, a solution containing metal; and
a controller that controls operation of the holding unit and operation of the supply unit, wherein
the controller is configured to execute:
a holding process including:
holding, before executing the thermal treatment, the substrate on which the silicon film is formed; and
an adhesion process including:
supplying, to the substrate that is held in the holding process, the solution containing the metal to cause the metal to adhere to a surface of the silicon film with an adhesion amount within a range equal to or more than 1.0E10 [atoms/cm2] and equal to or less than 1.0E20 [atoms/cm2].
